(19) United States
(12) Patent Application Publication
(10) Pub. No.: US 2025/0359030 A1
(43) Pub. Date: Nov. 20, 2025

(54) SEMICONDUCTOR DEVICE HAVING LANDING PAD AND METHOD FOR MANUFACTURING THE SAME

(71) Applicant: NANYA TECHNOLOGY CORPORATION, NEW TAIPEI CITY (TW)

(72) Inventor: JUNG-TZU PENG, NEW TAIPEI CITY (TW)

(21) Appl. No.: 18/741,062

(22) Filed: Jun. 12, 2024

Related U.S. Application Data
(62) Division of application No. 18/668,441, filed on May 20, 2024.

(51) Int. Cl. H10B 12/00

(52) U.S. Cl. CPC H10B 12/482; H10B 12/485; H10B 12/488

(57) ABSTRACT

A semiconductor device and a method of manufacturing a semiconductor device are provided. The semiconductor device includes a bit line extending in a first direction and an oxide film extending in a second direction and disposed over the bit line. The semiconductor device also includes a plurality of landing pads arranged along the oxide film.

### CROSS-REFERENCE TO RELATED APPLICATION

This application is a divisional application of U.S. Non-Provisional application Ser. No. 18/668,441 filed May 20, 2024, which is incorporated herein by reference in its entirety.

### TECHNICAL FIELD

The present disclosure relates to a semiconductor device and a method for manufacturing a semiconductor device, and more particularly, to a semiconductor device having a landing pad.

### DISCUSSION OF THE BACKGROUND

A semiconductor device may include a plurality of landing pads. Each of the landing pads may overlap a bit line and an adjacent contact hole associated with a respective capacitor. An upper portion of each of the landing pads can be electrically connected to a lower electrode of the respective capacitor. From a top view, the plurality of landing pads may have substantially polygonal shapes and be arranged in a zigzag pattern.

Conventionally, the multiple landing pads can be formed by LELE (litho-etch-litho-etch) and SADP (self-aligned double patterning) approaches. Conventional approaches may raise manufacturing costs due to complex process flows, and overlay control between the two patterning exposures becomes a critical issue.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a bit line extending in a first direction and an oxide film extending in a second direction and disposed over the bit line. The semiconductor device also includes a plurality of landing pads arranged along the oxide film.

Another aspect of the present disclosure provides a semiconductor device. The semiconductor device includes a substrate, a bit line disposed over the substrate, and a landing pad disposed over the bit line. An angle defined by the landing pad and a top surface of the bit line is about 70 to 90 degrees.

Another aspect of the present disclosure provides a method of manufacturing a semiconductor device. The method includes forming a plurality of oxide films on a substrate, disposing a landing pad material among the plurality of oxide films, and patterning the landing pad material by using a hard mask to form a plurality of landing pads.

By using an oxide film to define an alignment direction, the landing pads can be patterned using a single hard mask. Compared to using two hard masks, using one hard mask is better and easier for alignment because it simplifies the alignment process. In addition, using one hard mask reduces the number of alignment steps required, saving time and resources. Furthermore, a single hard mask can result in higher yield and reliability as it reduces the chances of defects and inconsistencies that may arise from using multiple hard masks. The performance and reliability of the semiconductor device can also be improved. Overall, using a single hard mask streamlines the manufacturing process and reduces the likelihood of errors, making it a more efficient and effective option.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

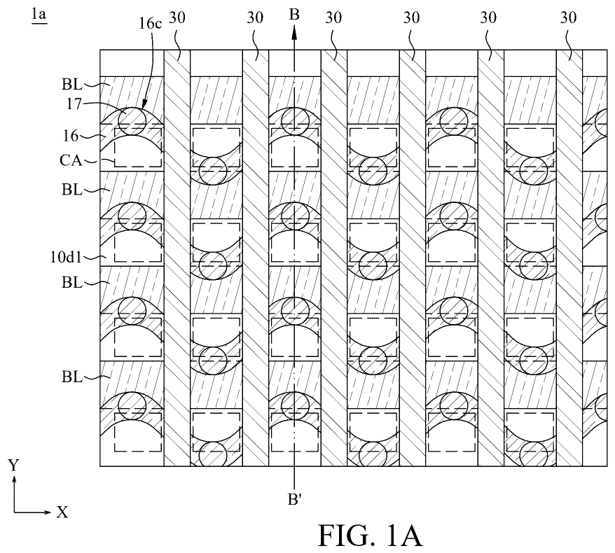

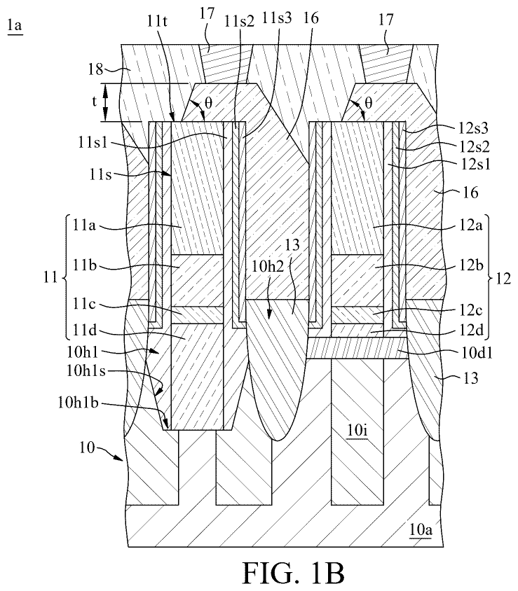

FIG. 1A is a schematic top view of a semiconductor device in accordance with some embodiments of the present disclosure.

FIG. 1B is a schematic cross-sectional view of a semiconductor device in accordance with some embodiments of the present disclosure.

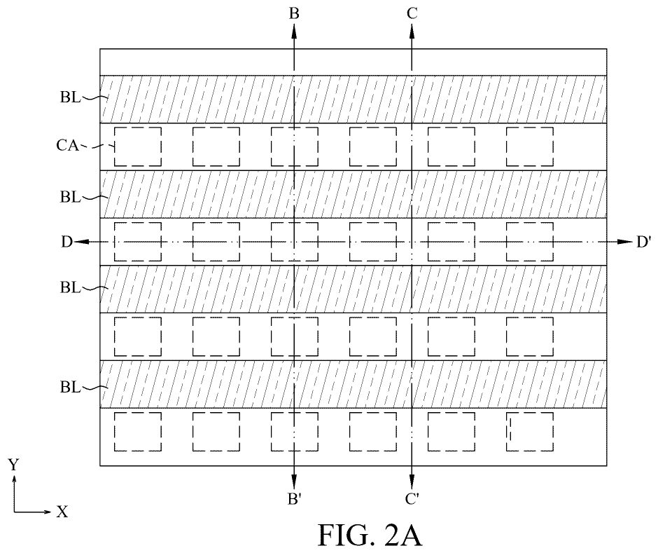

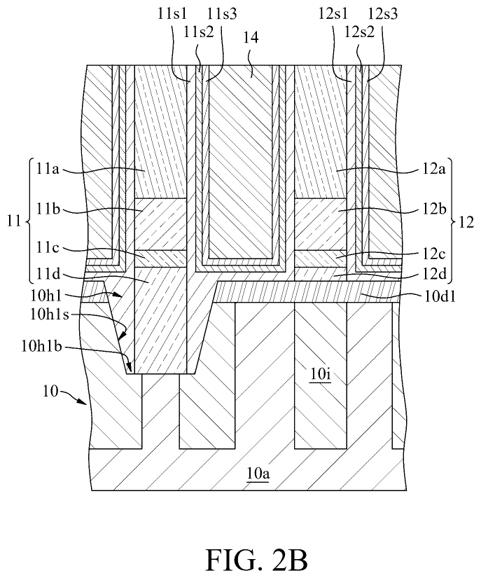

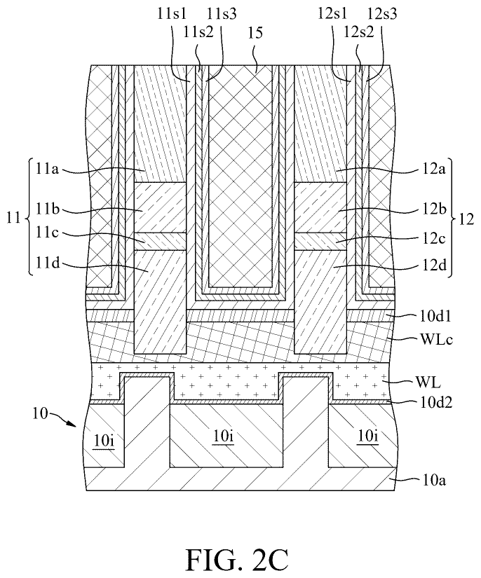

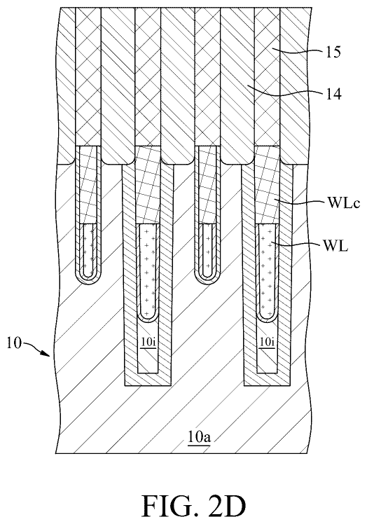

FIG. 2A is a schematic top view illustrating one or more stages of a method of manufacturing a semiconductor device in accordance with some embodiments of the present disclosure.

FIG. 2B is a schematic cross-sectional view illustrating one or more stages of a method of manufacturing a semiconductor device in accordance with some embodiments of the present disclosure.

FIG. 2C is a schematic cross-sectional view illustrating one or more stages of a method of manufacturing a semiconductor device in accordance with some embodiments of the present disclosure.

FIG. 2D is a schematic cross-sectional view illustrating one or more stages of a method of manufacturing a semiconductor device in accordance with some embodiments of the present disclosure.

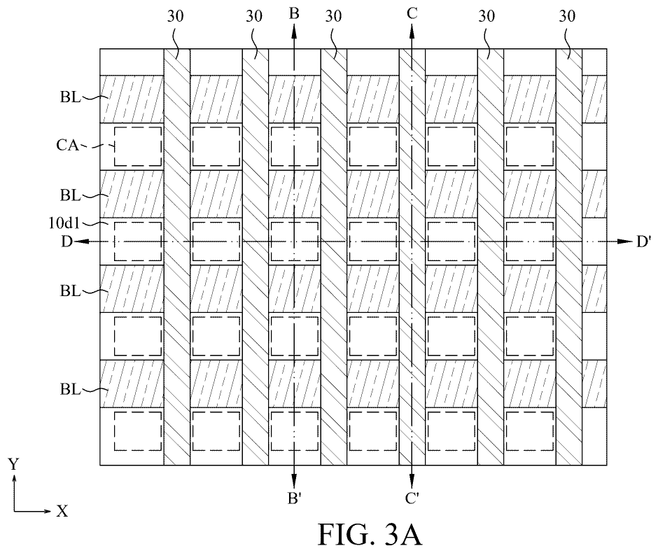

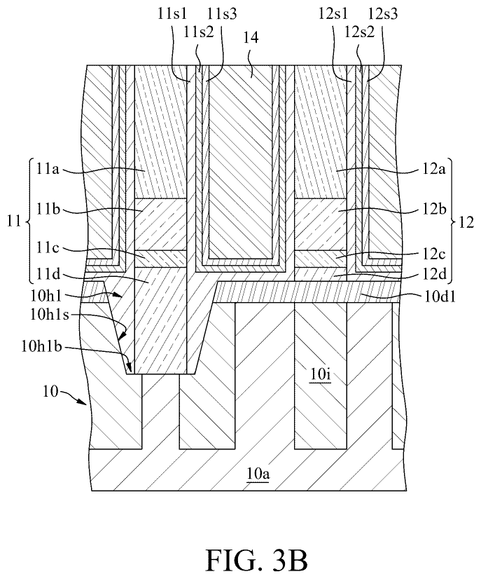

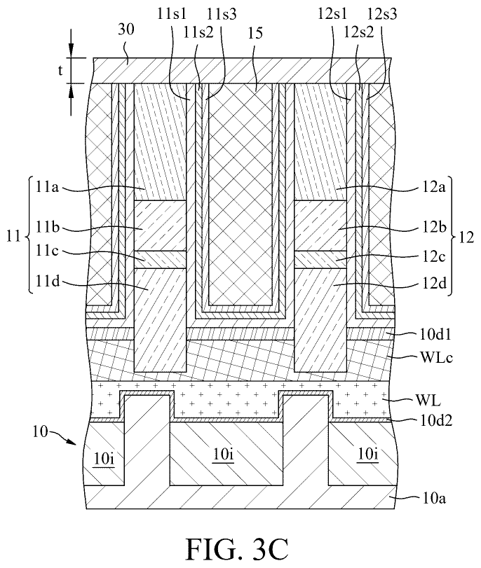

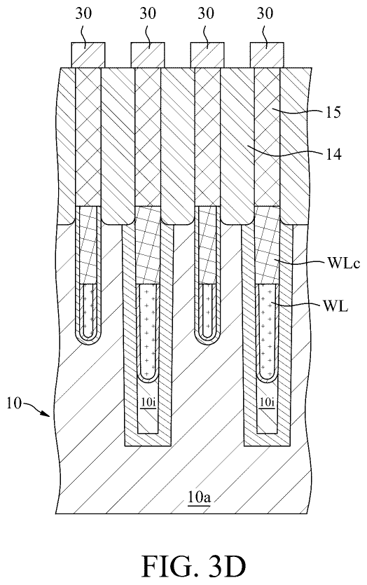

FIG. 3A is a schematic top view illustrating one or more stages of a method of manufacturing a semiconductor device in accordance with some embodiments of the present disclosure.

FIG. 3B is a schematic cross-sectional view illustrating one or more stages of a method of manufacturing a semiconductor device in accordance with some embodiments of the present disclosure.

FIG. 3C is a schematic cross-sectional view illustrating one or more stages of a method of manufacturing a semiconductor device in accordance with some embodiments of the present disclosure.

FIG. 3D is a schematic cross-sectional view illustrating one or more stages of a method of manufacturing a semiconductor device in accordance with some embodiments of the present disclosure.

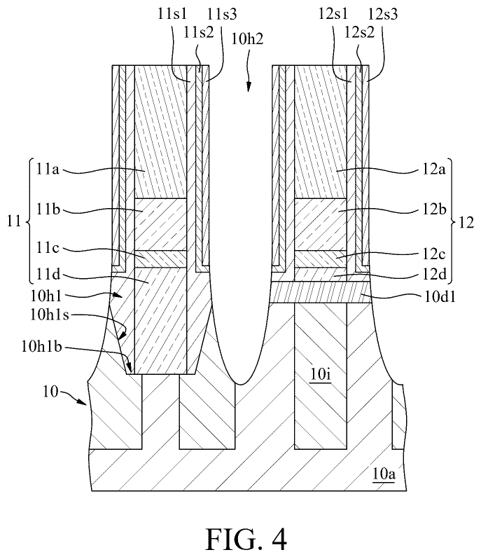

FIG. 4 is a schematic cross-sectional view illustrating one or more stages of a method of manufacturing a semiconductor device in accordance with some embodiments of the present disclosure.

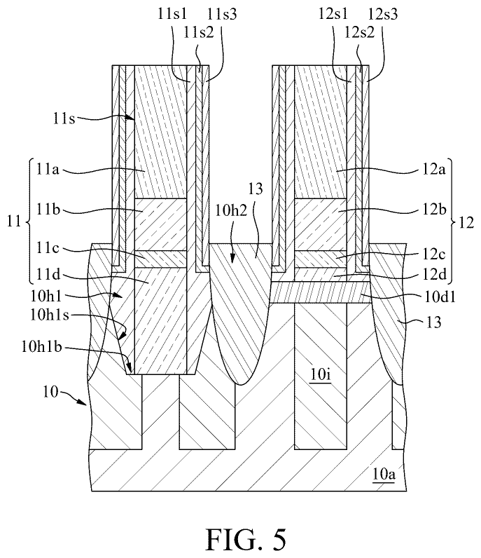

FIG. 5 is a schematic cross-sectional view illustrating one or more stages of a method of manufacturing a semiconductor device in accordance with some embodiments of the present disclosure.

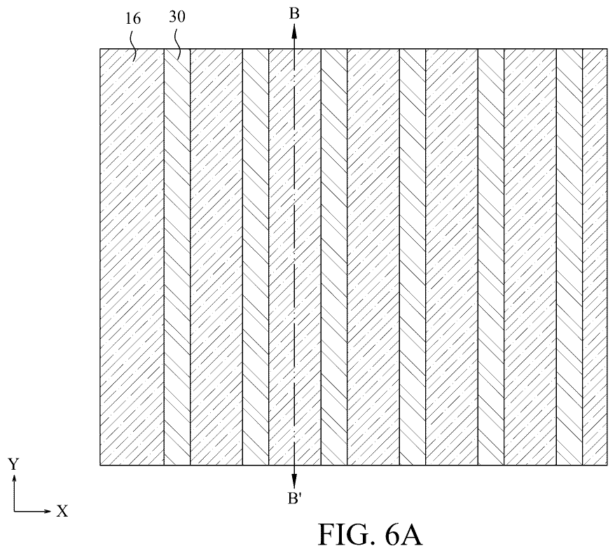

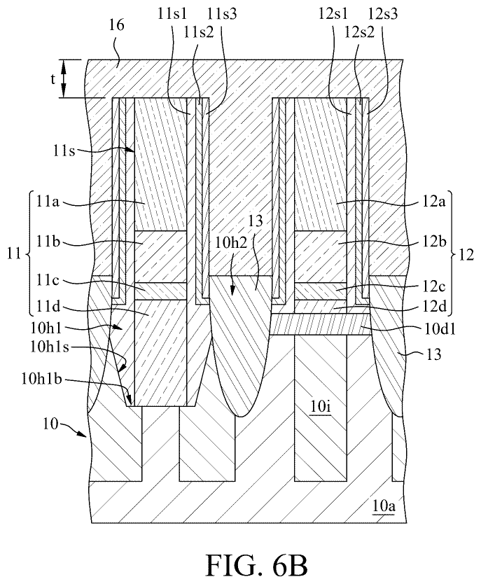

FIG. 6A is a schematic top view illustrating one or more stages of a method of manufacturing a semiconductor device in accordance with some embodiments of the present disclosure.

FIG. 6B is a schematic cross-sectional view illustrating one or more stages of a method of manufacturing a semiconductor device in accordance with some embodiments of the present disclosure.

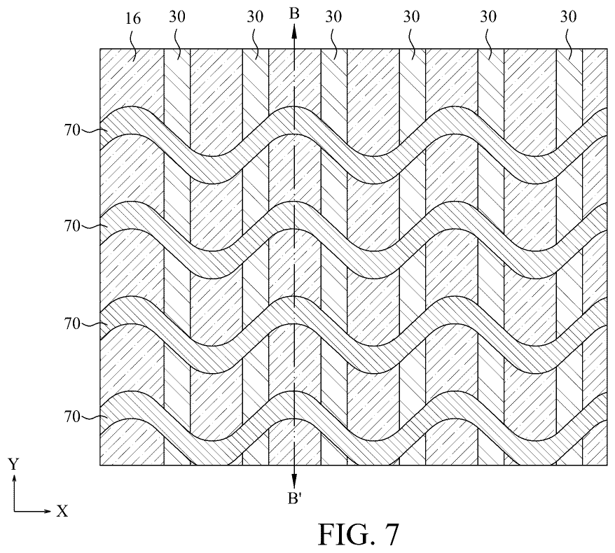

FIG. 7 is a schematic top view illustrating one or more stages of a method of manufacturing a semiconductor device in accordance with some embodiments of the present disclosure.

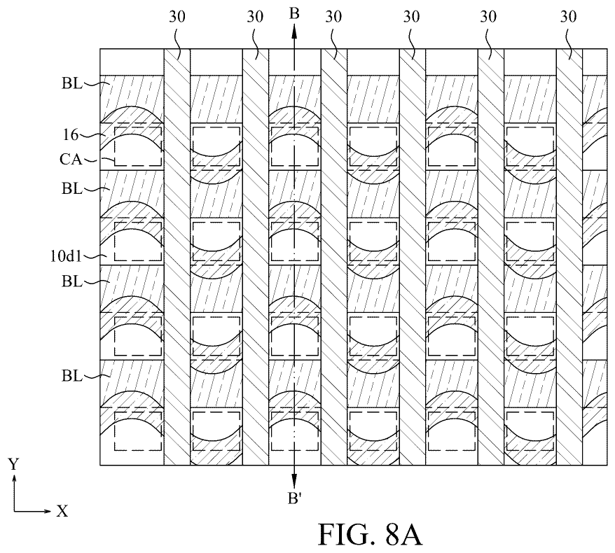

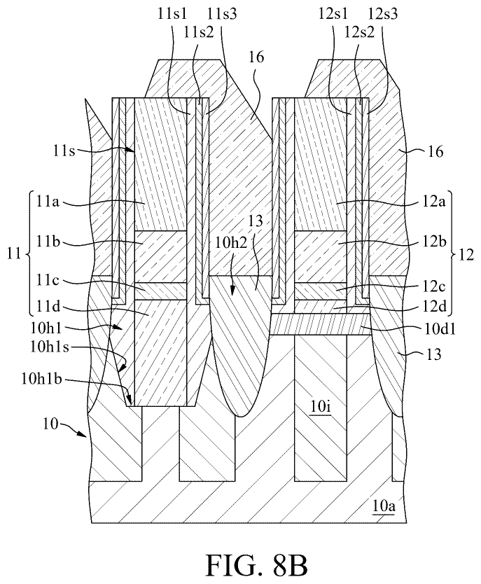

FIG. 8A is a schematic top view illustrating one or more stages of a method of manufacturing a semiconductor device in accordance with some embodiments of the present disclosure.

FIG. 8B is a schematic cross-sectional view illustrating one or more stages of a method of manufacturing a semiconductor device in accordance with some embodiments of the present disclosure.

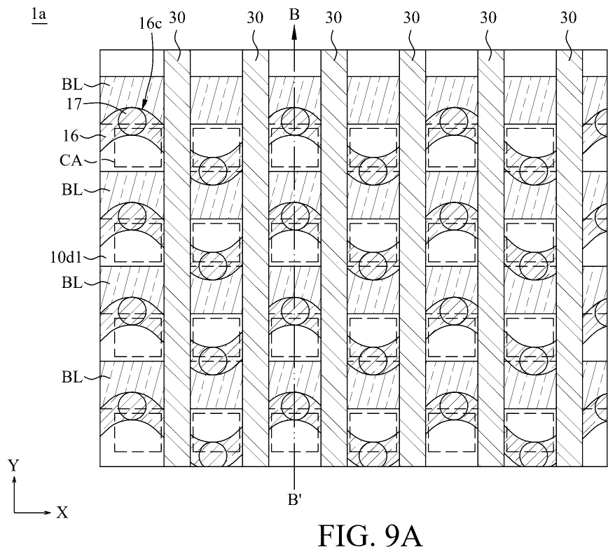

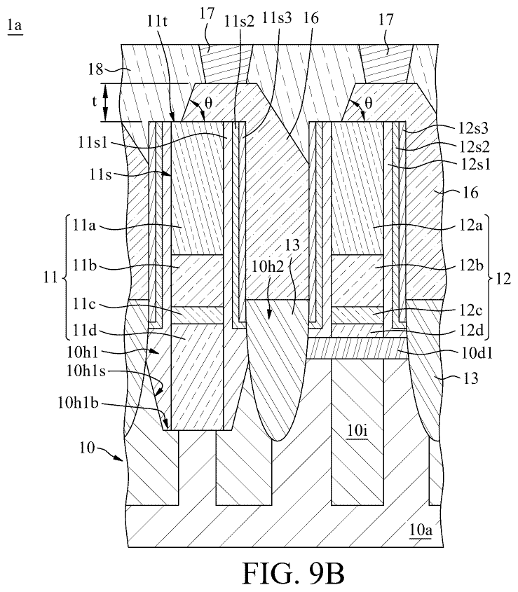

FIG. 9A is a schematic top view illustrating one or more stages of a method of manufacturing a semiconductor device in accordance with some embodiments of the present disclosure.

FIG. 9B is a schematic cross-sectional view illustrating one or more stages of a method of manufacturing a semiconductor device in accordance with some embodiments of the present disclosure.

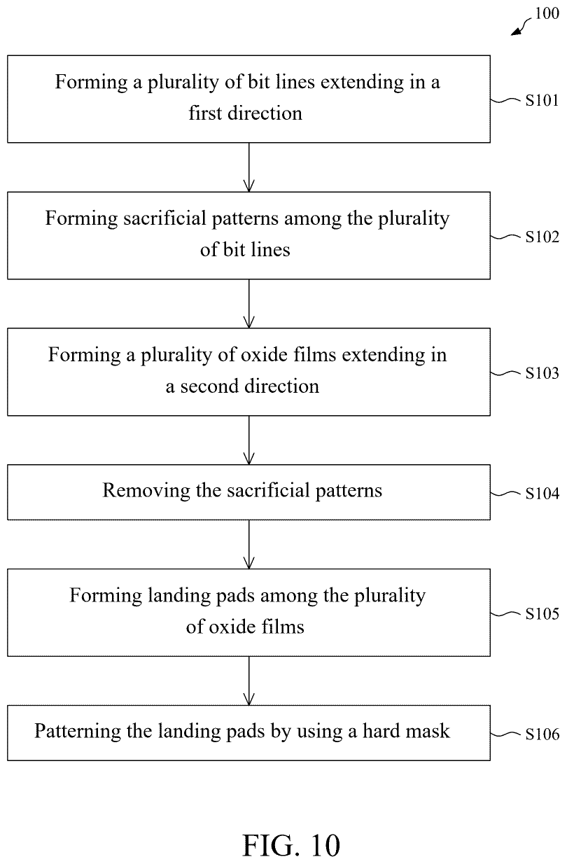

FIG. 10 illustrates a flow chart of a method of manufacturing a semiconductor device in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

FIG. 1A is a schematic top view of a semiconductor device 1a in accordance with some embodiments of the present disclosure. FIG. 1B illustrates a cross-sectional view of the semiconductor device 1a taken along lines B-B′ of FIG. 1A.

In some embodiments, the semiconductor device 1a may be disposed adjacent to a circuit. For example, the semiconductor device 1a may be disposed adjacent to a memory device such as a dynamic random access memory (DRAM) device or the like.

Referring to FIG. 1A, the semiconductor device 1a may include a plurality of bit lines BL extending in a first direction X and a plurality of oxide films 30 extending in a second direction Y crossing the bit lines BL. The second direction Y may be distinct from the first direction X. The second direction Y may be substantially perpendicular to the first direction X. The oxide films 30 may be striated or have a stripe structure.

The oxide films 30 may be substantially overlapped with the word lines (such as the word lines WL in FIGS. 3C and 3D). The oxide films 30 may partially cover the bit lines BL. For example, the oxide films 30 may be disposed higher than the bit lines BL.

The oxide films 30 and the bit lines BL form or define a plurality of grids. The semiconductor device 1a may include a plurality of contact areas CA. The contact areas CA may each be formed in a grid defined by the oxide films 30 and the bit lines BL. The contact areas CA may be separated from one another by an interlayer 10d1.

The contact areas CA may include a contact hole (such as the recess region 10h2 in FIG. 1B) and may be electrically connected with a memory element through a storage node contact (such as the storage node contact 13 in FIG. 1B). In some embodiments, the memory element may be a capacitor, and may include a lower electrode 17, an upper electrode and a dielectric layer therebetween. In other embodiments, the memory element may be a variable resistance pattern capable of switching between two resistance states by an electrical pulse applied to the memory element. For example, the memory element may include a phase change material capable of changing a crystalline state according to an amount of electrical current, such as perovskite compounds, transition metal oxide, magnetic materials, ferromagnetic materials or antiferromagnetic materials.

The semiconductor device 1a may include a plurality of landing pads 16. The landing pads 16 may be aligned by the oxide films 30. The landing pads 16 may be arranged along the oxide films 30. The landing pads 16 may each overlapped with one of the bit lines BL and one of the contact areas CA. The landing pads 16 may each be electrically connected to a lower electrode 17 of the respective capacitor. The landing pads 16 may be alternately arranged on two adjacent bit lines BL along the first direction X.

The landing pads 16 may each have a dimension (or an area) that is 10 to 30% larger than a dimension (or an area) of the lower electrode 17.

The landing pads 16 may each have an area overlapping one of the bit lines BL, which is greater than an area overlapping one of the contact areas CA. For example, about 50 to 100 percent of the area of one of the landing pads 16 overlaps the bit lines BL.

The landing pads 16 may each have two curved surfaces and two straight surfaces. The centre of curvature of the two curved surfaces may be at the same side of the landing pad 16. One of the curved surfaces (such as the curved surface 16c) may overlap one of the bit lines BL. The centre of curvature of the landing pads 16 may be aligned in the second direction Y.

Referring to FIG. 1B, the semiconductor device 1a may include a substrate 10 and bit lines 11 and 12. The bit lines 11 and 12 may be disposed over the substrate 10. The bit lines 11 and 12 may be two adjacent bit lines BL in FIG. 1A.

The substrate 10 may include a semiconductor substrate. In some embodiments, the semiconductor material of the substrate 10 may include, for example, silicon (Si) (such as monocrystalline silicon, polysilicon, and amorphous silicon), germanium (Ge), gallium (Ga), and indium (In). In some embodiments, the semiconductor material of the substrate 10 may include a compound semiconductor including silicon germanium (SiGe), silicon carbide (SiC), silicon germanium carbide (SiGeC), gallium arsenide (GaAs), gallium phosphide (GaP), indium arsenide (InAs), indium phosphide (InP), indium antimonide (InSb), or other IV-IV, III-V or II-VI semiconductor materials.

In some embodiments, the substrate 10 may include a bulk semiconductor, a semiconductor-on-insulator (SOI) substrate, a multi-layered substrate, or a gradient substrate. For example, the SOI substrate may include a layer of a semiconductor material formed on an insulator layer. The insulator layer may be, for example, a buried oxide (BOX) layer, a silicon oxide layer, or the like. The insulator layer may be provided on a substrate, typically a silicon or glass substrate. In some embodiments, the substrate 10 may be a wafer, such as a silicon wafer. The substrate 10 may be doped (e.g., with a P-type or an N-type dopant) or undoped.

The substrate 10 may include an active region 10a and a plurality of isolation regions 10i. In some embodiments, the isolation region 10i may include shallow trench isolation (STI) structures.

A wall oxide, a liner and a gap-fill dielectric may be sequentially formed as the isolation region 10i. The liner may be formed by stacking silicon oxide (SiO₂) and silicon nitride (Si₃N₄). The gap-fill dielectric may include, for example, silicon oxide (SiO₂), silicon nitride (Si₃N₄), a low-k (e.g., having a dielectric constant less than that of silicon oxide, which is about 3.9) dielectric material (e.g., phosphosilicate glass (PSG), borosilicate glass (BSG), boron-doped phosphosilicate glass (BPSG), undoped silicate glass (USG), etc.), the like, or combinations thereof. In another embodiment, in the isolation region 10i, a silicon nitride may be used as the gap-fill dielectric.

In some embodiments, a doped region may be disposed over or proximal to the top surface of the active region 10a. The doped region may be doped with an N-type dopant such as phosphorus (P), arsenic (As), or antimony (Sb). In some other embodiments, the doped region may be doped with a P-type dopant such as boron (B) or indium (In).

An interlayer 10d1 may be disposed on the substrate 10. The interlayer 10d1 may be disposed on the top surface of the active region 10a. The interlayer 10d1 may be formed of either a single insulating layer or a plurality of insulating layers. The interlayer 10d1 may include an isolating material or a dielectric material. The interlayer 10d1 may include, for example, silicon oxide (SiO₂), silicon nitride (Si₃N₄) and/or silicon oxynitride.

A recess region 10h1 may be formed in the substrate 10. The bit line 11 may be disposed in the recess region 10h1 and contact (such as directly contact) the active region 10a.

The recess region 10h1 may recess into the substrate 10 from the top surface of the active region 10a and/or from the interlayer 10d1. The recess region 10h1 may have a sidewall 10h1s and a bottom surface 10h1b. The sidewall 10h1s may extend from the bottom surface 10h1b to the top surface of the active region 10a and/or the interlayer 10d1.

The sidewall 10h1s of the recess region 10h1 may be inclined with respect to the top surface of the active region 10a and/or the interlayer 10d1. The recess region 10h1 may narrow or taper toward the interior of the substrate 10. In some embodiments, the sidewall 10h1s of the recess region 10h1 may be substantially perpendicular to the top surface of the active region 10a and/or the interlayer 10d1.

A recess region 10h2 may be formed in the substrate 10 for accommodating the storage node contact 13. The recess region 10h2 may recess from the top surface of the active region 10a and/or from the interlayer 10d1. The recess region 10h2 may be adjacent to the recess region 10h1.

The storage node contact 13 may penetrate the interlayer 10d1 to contact (such as directly contact) the active region 10a. The bottom surface of the storage node contact 13 may be positioned lower than the bottom surface 10h1b of the recess region 10h1.

The bit line 11 may include a bit line contact 11d and stacked patterns (such as a conductive pattern 11c, a conductive pattern 11b, and a bit line capping pattern 11a).

The bit line contact 11d may be disposed in the recess region 10h1. The bit line contact 11d may include a doped polysilicon.

The conductive pattern 11c may include any suitable material, such as titanium (Ti), tantalum (Ta), titanium nitride (TiN), tantalum nitride (TaN), tungsten nitride (W₂N, WN, WN₂), the like, or combinations thereof.

The conductive pattern 11b may include any suitable metal, such as tungsten (W), copper (Cu), ruthenium (Ru), aluminum (Al), gold (Au), cobalt (Co), the like, or combinations thereof.

The bit line capping pattern 11a may include, for example, silicon oxide (SiO₂), silicon nitride (Si₃N₄) and/or silicon oxynitride.

The bit line 11 may include spacers 11s1, 11s2, and 11s3 formed on both sidewalls 11s of the bit line 11.

The spacers 11s1 and 11s3 may each include a nitrogen-containing material, such as silicon nitride (Si₃N₄). The spacer 11s2 may include an oxygen-containing material, such as silicon oxide (SiO₂).

The bit line 12 may be spaced apart from (or separated from) the bit line 11 by the storage node contact 13. The bit line 12 may be disposed over the interlayer 10d1. The bit line 12 may be spaced apart from (or separated from) the substrate 10 by the interlayer 10d1.

The bit line 12 may include a bit line contact 12d and stacked patterns (such as a conductive pattern 12c, a conductive pattern 12b, and a bit line capping pattern 12a). The bit line 12 may include spacers 12s1, 12s2, and 12s3 formed on both sidewalls of the bit line 12. The detailed descriptions of the bit line 12 may refer to detailed descriptions of the bit line 11 provided above, which will not be repeated for the sake of brevity.

The landing pad 16 may be disposed between the adjacent bit lines, such as the bit lines 11 and 12. The landing pad 16 may be electrically connected to the storage node contact 13.

The landing pad 16 and the storage node contact 13 may each include a conductive material. The landing pad 16 and the storage node contact 13 may each include a doped semiconductor material (e.g., doped silicon), a metal (e.g., tungsten, titanium, and tantalum), a conductive metal nitride (e.g., titanium nitride, tantalum nitride, and tungsten nitride), and a metal-semiconductor compound (e.g., a metal silicide).

A thickness t of the landing pad 16 on the top surface 11t of the bit line 11 may be substantially equal to the thickness of the oxide film 30 (such as the thickness t of the oxide film 30 in FIG. 3C).

The landing pad 16 may have a tapered structure. For example, the landing pad 16 may taper away from the bit line 11. An angle θ defined by the landing pad 16 and the top surface 11t of the bit line 11 may be about 70 to 90 degrees.

The landing pad 16 may be surrounded by an interlayer 18. For example, the interlayer 18 may be disposed over the substrate 10 to cover the landing pad 16.

The lower electrode 17 may be disposed over the landing pad 16. The lower electrode 17 may be vertically overlapped with the bit line 11. The lower electrode 17 may be electrically connected to the storage node contact 13.

The lower electrode 17 may include a doped semiconductor material (e.g., doped silicon), a metal (e.g., tungsten, titanium, and tantalum), a conductive metal nitride (e.g., titanium nitride, titanium aluminum nitride, titanium silicon nitride, tantalum nitride, tantalum aluminum nitride, tantalum silicon nitride, and tungsten nitride), a conductive metal oxide (e.g., iridium oxide), or other conductive materials.

FIGS. 2A, 2B, 2C, 2D, 3A, 3B, 3C, 3D, 4, 5, 6A, 6B, 7, 8A, 8B, 9A, and 9B illustrate stages of a method of manufacturing a semiconductor device in accordance with some embodiments of the present disclosure. At least some of these figures have been simplified for a better understanding of the aspects of the present disclosure. In some embodiments, the semiconductor device 1a in FIG. 1A may be manufactured by the operations described below with respect to FIGS. 2A, 2B, 2C, 2D, 3A, 3B, 3C, 3D, 4, 5, 6A, 6B, 7, 8A, 8B, 9A, and 9B.

As shown in FIG. 2A, the semiconductor device 1a may include a plurality of bit lines BL extending in the first direction X and a plurality of contact areas CA arranged in a line between any two of the bit lines BL. The word lines (such as the word line WL) are not shown in FIG. 2A. The word lines and the bit lines BL may form or define a plurality of grids. The contact areas CA may each be formed in a grid defined by the word lines and the bit lines BL.

FIG. 2B illustrates a cross-sectional view of the semiconductor device taken along lines B-B′ of FIG. 2A. The semiconductor device 1a may include a substrate 10 and bit lines 11 and 12. Sacrificial patterns 14 may be formed among the plurality of bit lines (such as the bit lines 11 and 12). The sacrificial patterns 14 may have an etching selectivity with respect to the materials of the spacers 11s3 and 12s3. For example, the sacrificial patterns 14 may have an etching rate higher than the materials of the spacers 11s3 and 12s3. For example, the sacrificial patterns 14 may be formed of a spin-on-hard mask (SOH) material (e.g., SOH silicon oxide).

FIG. 2C illustrates a cross-sectional view of the semiconductor device taken along lines C-C′ of FIG. 2A. The active region 10a may protrude more than the isolation region 10i. A dielectric layer 10d2 may be conformally formed on the active region 10a and the isolation region 10i.

The word line WL may be disposed over the dielectric layer 10d2. The word line WL may include a gate electrode. The word line WL may extend through the active regions 10a and the isolation region 10i. A capping layer WLc of the word-line WL may be disposed on the gate electrode of the word line WL. The capping layer WLc may serve to protect the gate electrode of the word line WL.

The bit line contact 11d of the bit line 11 may be partially surrounded by the capping layer WLc. The bit line contact 12d of the bit line 12 may be partially surrounded by the capping layer WLc.

An insulating pattern 15 may be formed between the bit line 11 and the bit line 12. For example, the insulating pattern 15 may be disposed over the spacer 11s3 and the spacer 12s3.

The insulating patterns 15 may include an insulating material having an etch selectivity with respect to the sacrificial patterns 14. For example, the insulating patterns 15 may include, for example, silicon oxide (SiO₂), silicon nitride (Si₃N₄) and/or silicon oxynitride.

FIG. 2D illustrates a cross-sectional view of the semiconductor device taken along lines D-D′ of FIG. 2A. In some embodiments, the sacrificial patterns 14 and the insulating patterns 15 may be formed alternately and may be arranged along the first direction X in FIG. 2A.

As shown in FIG. 3A, a plurality of oxide films 30 may be formed on the semiconductor device. The oxide films 30 may extend in the second direction Y crossing the bit lines BL. The oxide films 30 may be striated or have a stripe structure.

The oxide films 30 may be formed by disposing an oxide film and etching the oxide film through a hard mask. Portions of the oxide film may be covered by the hard mask. Portions other than the portions covered by the hard mask may be etched. The oxide films 30 may be configured to define locations of the plurality of landing pads formed in the operation in FIG. 8A. The oxide films 30 may be configured to align the plurality of landing pads formed in the operation in FIG. 8A.

FIG. 3B illustrates a cross-sectional view of the semiconductor device taken along lines B-B′ of FIG. 3A. After the oxide film 30 is partially etched, the sacrificial patterns 14 may be exposed from the oxide film 30. Therefore, the oxide film 30 is not shown in FIG. 3A.

FIG. 3C illustrates a cross-sectional view of the semiconductor device taken along lines C-C′ of FIG. 3A. The oxide films 30 may be substantially overlapped with the word lines WL. The oxide films 30 may cover the bit lines BL. For example, the oxide films 30 may be disposed above the bit lines BL. The thickness t of the oxide film 30 may define the thickness of the landing pad 16 on the top surface 11t of the bit line 11 shown in FIG. 6B.

FIG. 3D illustrates a cross-sectional view of the semiconductor device taken along lines D-D′ of FIG. 3A. The locations of the oxide films 30 may substantially correspond to the locations of the word lines WL. In some embodiments, the spacing between two adjacent oxide films 30 may be configured to define the shortest distance between the landing pads in the first direction X.

As shown in FIG. 4, the sacrificial patterns 14 may be removed by using a suitable etching operation, such as a directional or anisotropic dry etching operation. After the etching operation, the recess region 10h2 may be formed in the substrate 10 to expose the active region 10a.

As shown in FIG. 5, a material of the storage node contact 13 may be disposed in the recess region 10h2. The material of the storage node contact 13 may be disposed adjacent to the bit line 11. Subsequently, a recessing process may be performed on the material of the storage node contact 13. The recessing process may be performed by a dry etch process, for example, an etch-back process.

As shown in FIG. 6A, a material of the landing pad 16 may be filled in the space defined by the oxide films 30. The material of the landing pad 16 may be formed by any suitable process, such as chemical vapor deposition (CVD) or physical vapor deposition (PVD). The landing pad 16 may include a doped semiconductor material (e.g., doped silicon), a metal (e.g., tungsten, titanium, and tantalum), a conductive metal nitride (e.g., titanium nitride, tantalum nitride, and tungsten nitride), and a metal-semiconductor compound (e.g., a metal silicide).

FIG. 6B illustrates a cross-sectional view of the semiconductor device taken along lines B-B′ of FIG. 6A. The material of the landing pad 16 may cover the bit lines 11 and 12. The thickness t of the material of the landing pad 16 on the top surface 11t of the bit line 11 may be substantially the same as the thickness of the oxide film 30 (such as the thickness t of the oxide film 30 in FIG. 3C).

As shown in FIG. 7, hard masks 70 may be formed to define the shapes of the landing pads 16. For example, the hard masks 70 may each be bordered by a line formed of alternating shallow curves. For example, the hard masks 70 may each have a shape or edge that is smoothly curved in and out. In some embodiments, the hard masks 70 may be configured to define the shape, width, and area of the landing pad 16.

As shown in FIG. 8A, the material of the landing pad 16 may be patterned. Portions of the material of the landing pad 16 that are exposed from the hard masks 70 may be etched away by using a suitable etching operation, such as a directional or anisotropic dry etching operation. Therefore, a plurality of landing pads 16 may be formed. The plurality of landing pads 16 may be separated from one another. The plurality of landing pads 16 may be aligned by the oxide films 30.

FIG. 8B illustrates a cross-sectional view of the semiconductor device taken along lines B-B′ of FIG. 8A. After the etching operation, the landing pad 16 may have a tapered structure. For example, the landing pad 16 may taper away from the bit line 11. An angle θ defined by the landing pad 16 and the top surface 11t of the bit line 11 may be about 70 to 90 degrees.

As shown in FIG. 9A, the lower electrode 17 may be disposed over the landing pad 16. The lower electrode 17 may be formed by any suitable process, such as chemical vapor deposition (CVD) or physical vapor deposition (PVD).

FIG. 9B illustrates a cross-sectional view of the semiconductor device taken along lines B-B′ of FIG. 9A. The lower electrode 17 may be disposed within the contact hole in the interlayer 18.

In a conventional process, the multiple landing pads can be formed by LELE (litho-etch-litho-etch) and SADP (self-aligned double patterning) approaches. For example, two different hard masks may be used to define the shapes of the landing pads. Conventional approaches may increase the manufacturing cost due to complex process flows, and overlay control between the two patterning exposures becomes a critical issue.

By disposing the oxide films 30 over the bit lines BL before disposing the material of the landing pads, the oxide films 30 can be used to define an alignment direction of the landing pads. Therefore, the landing pads can be patterned merely using a single hard mask.

Compared to using two hard masks, using one hard mask is better and easier for alignment because it simplifies the alignment process. In addition, using one hard mask reduces the number of alignment steps required, saving time and resources. Furthermore, a single hard mask can result in higher yield and reliability as it reduces the chances of defects and inconsistencies that may arise from using multiple hard masks. The performance and reliability of the semiconductor device can also be improved. Overall, using a single hard mask streamlines the manufacturing process and reduces the likelihood of errors, making it a more efficient and effective option.

FIG. 10 illustrates a flow chart of a method 100 of manufacturing a semiconductor device in accordance with some embodiments of the present disclosure.

In some embodiments, the method 100 may include a step S101 of forming a plurality of bit lines extending in a first direction. For example, as shown in FIG. 2A, the semiconductor device 1a may include a plurality of bit lines BL extending in the first direction X.

In some embodiments, the method 100 may include a step S102 of forming sacrificial patterns among the plurality of bit lines. For example, as shown in FIG. 2B, sacrificial patterns 14 may be formed among the plurality of bit lines (such as the bit lines 11 and 12).

In some embodiments, the method 100 may include a step S103 of forming a plurality of oxide films extending in a second direction. For example, as shown in FIG. 3A, the oxide films 30 may extend in the second direction Y crossing the bit lines BL. The oxide films 30 may be striated or have a stripe structure.

In some embodiments, the method 100 may include a step S104 of removing the sacrificial patterns. For example, as shown in FIG. 4, the sacrificial patterns 14 may be removed by using a suitable etching operation, such as a directional or anisotropic dry etching operation. After the etching operation, the recess region 10h2 may be formed in the substrate 10 to expose the active region 10a.

In some embodiments, the method 100 may include a step S105 of forming landing pads among the plurality of oxide films. For example, as shown in FIG. 6A, a material of the landing pad 16 may be filled in the space defined by the oxide films 30.

In some embodiments, the method 100 may include a step S106 of patterning the landing pads by using a hard mask. For example, as shown in FIG. 8A, the material of the landing pad 16 may be patterned. Portions of the material of the landing pad 16 that are exposed from the hard masks 70 may be etched away by using a suitable etching operation, such as a directional or anisotropic dry etching operation. Therefore, a plurality of landing pads 16 may be formed.

One aspect of the present disclosure provides a semiconductor device. The semiconductor device includes a bit line extending in a first direction and an oxide film extending in a second direction and disposed over the bit line. The semiconductor device also includes a plurality of landing pads arranged along the oxide film.

Another aspect of the present disclosure provides a semiconductor device. The semiconductor device includes a substrate, a bit line disposed over the substrate, and a landing pad disposed over the bit line. An angle defined by the landing pad and a top surface of the bit line is about 70 to 90 degrees.

Another aspect of the present disclosure provides a method of manufacturing a semiconductor device. The method includes forming a plurality of oxide films on a substrate, disposing a landing pad material among the plurality of oxide films, and patterning the landing pad material by using a hard mask to form a plurality of landing pads. By using an oxide film to define an alignment direction, the landing pads can be patterned using a single hard mask. Compared to using two hard masks, using one hard mask is better and easier for alignment than using two hard masks because it simplifies the alignment process. In addition, using one hard mask reduces the number of alignment steps required, saving time and resources.

Furthermore, a single hard mask can result in higher yield and reliability as it reduces the chances of defects and inconsistencies that may arise from using multiple hard masks. The performance and reliability of the semiconductor device can also be improved. Overall, using a single hard mask streamlines the manufacturing process and reduces the likelihood of errors, making it a more efficient and effective option.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate;
a bit line disposed over the substrate; and
a landing pad disposed over the bit line, wherein an angle defined by the landing pad and a top surface of the bit line is about 70 to 90 degrees.

2. The semiconductor device of claim 1, wherein the landing pad tapers away from the bit line.

3. The semiconductor device of claim 1, wherein a curved surface of the landing pad overlaps the bit line.

4. The semiconductor device of claim 1, wherein about 50 to 100 percent of an area of the landing pad overlaps the bit line.

5. The semiconductor device of claim 1, further comprising:
an oxide film disposed higher than the bit line with respect to the substrate.

6. The semiconductor device of claim 5, wherein a thickness of the landing pad on the top surface of the bit line is substantially equal to a thickness of the oxide film.

7. The semiconductor device of claim 6, wherein the oxide film is configured to align a plurality of landing pads over the substrate.

8. The semiconductor device of claim 6, wherein the oxide film overlaps a word line on the substrate.

9. The semiconductor device of claim 8, wherein the bit line extends in a first direction, and the oxide film and the word line extend in a second direction.

10. The semiconductor device of claim 1, further comprising:
a contact area under the landing pad.

11. The semiconductor device of claim 10, further comprising:
a lower electrode electrically connected with the contact area through the landing pad.
